(19) United States
(12) Patent Application Publication
(10) Pub. No.: US 2023/0020387 A1
(43) Pub. Date: Jan. 19, 2023

(54) LOW TEMPERATURE SINTERED COATINGS FOR PLASMA CHAMBERS

(71) Applicant: LAM RESEARCH CORPORATION, Fremont, CA (US)

(72) Inventors: David Joseph WETZEL, Santa Clara, CA (US); Lin XU, Fremont, CA (US); John DAUGHERTY, Fremont, CA (US); John Michael KERNS, Livermore, CA (US); Satish SRINIVASAN, Newark, CA (US); Robin KOSHY, Fremont, CA (US); Michael LOPEZ, Redwood City, CA (US); Douglas DETERT, Berkeley, CA (US)

(21) Appl. No.: 17/777,656

(22) PCT Filed: Nov. 19, 2020
(86) PCT No.: PCT/US2020/061168

§ 371 Date: May 18, 2022

Related U.S. Application Data
(60) Provisional application No. 62/939,353, filed on Nov. 22, 2019.

(51) Int. Cl. C23C 16/40; C23C 4/11; H01J 37/32; C23C 16/56; C23C 14/08; C23C 14/58

(52) U.S. Cl. CPC C23C 16/405; C23C 4/11; H01J 37/32119; H01J 37/32477; C23C 16/56; C23C 14/083; C23C 14/5806

(57) ABSTRACT

A method for forming a coating on a component of a substrate processing system includes arranging the component in a processing chamber and applying a ceramic material to form the coating on one or more surfaces of the component. The ceramic material is comprised of a mixture including a rare earth oxide and having a grain size of less than 150 nm and is applied while a temperature within the processing chamber is less than 400° C. The coating has a thickness of less than 30 μm. A heat treatment process is performed on the coated component in a heat treatment chamber. The heat treatment process includes increasing a temperature of the heat treatment chamber from a first temperature to a second temperature that does not exceed a melting temperature of the mixture over a first period and maintaining the second temperature for a second period.

### CROSS-REFERENCE TO RELATED APPLICATIONS

This application claims the benefit of U.S. Provisional Application No. 62/939,353, filed on Nov. 22, 2019. The entire disclosure of the application referenced above is incorporated herein by reference.

### FIELD

The present disclosure relates to protective coatings for components in plasma substrate processing chambers.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, and/or other etch, deposition, or cleaning processes. A substrate may be arranged on a substrate support, such as a pedestal, an electrostatic chuck (ESC), etc. in a processing chamber of the substrate processing system. During etching, gas mixtures including one or more precursors may be introduced into the processing chamber and plasma may be used to initiate chemical reactions.

### SUMMARY

A method for forming a coating on a component of a substrate processing system includes arranging the component in a processing chamber and applying a ceramic material to form the coating on one or more surfaces of the component. The ceramic material is comprised of a mixture including a rare earth oxide and a grain size of the mixture is less than 150 nm and is applied while a temperature within the processing chamber is less than 400 degrees Celsius. The coating has a thickness of less than 30 μm. The method further includes arranging the component in a heat treatment chamber and performing a heat treatment process on the component including the coating. The heat treatment process includes increasing a temperature of the heat treatment chamber from a first temperature to a second temperature over a first period and maintaining the heat treatment chamber at the second temperature for a second period. The second temperature does not exceed a melting temperature of the mixture.

In other features, the processing chamber is configured to perform plasma etching. The component is a dielectric window. Applying the ceramic material includes applying the ceramic material using aerosol deposition. Applying the ceramic material includes applying the ceramic material using at least one of physical vapor deposition, chemical vapor deposition, and thermal spraying. The mixture includes yttrium oxide. The second temperature is less than 1400 degrees Celsius. The second temperature is less than 1300 degrees Celsius.

In other features, the mixture includes at least one of ytterbium, erbium, dysprosium, gadolinium, thulium, and aluminum. The grain size is less than 100 nm.

The thickness of the coating is 3-20 μm. The first period is between 5 and 30 hours and the second period is between 8 and 144 hours. The temperature of the heat treatment chamber is increased during the first period at a predetermined ramp rate. The ramp rate is 30-100 degrees Celsius per hour.

In other features, the method includes increasing the second temperature to a third temperature over a third period and maintaining the heat treatment chamber at the third temperature for a fourth period. The third temperature does not exceed the melting temperature of the mixture. Subsequent to the heat treatment process, the coating has a porosity less than 20%. Subsequent to the heat treatment process, the coating has an average grain size between 200 and 700 nm. Subsequent to the heat treatment process, the coating has a surface roughness less than 0.1 Sa. Subsequent to the heat treatment process, the coating experiences less than 30 nm of erosion caused by a one hour acid soak test in a 5% hydrogen chloride solution.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system according to the present disclosure;

FIGS. 2A through 2E show a coating and sintering process according to the present disclosure; and

FIG. 3 illustrates steps of an example method for applying and performing a heat treatment on a coating of a component of a substrate processing chamber according to the present disclosure.

In the drawings, reference numbers may be reused to identify similar and/or identical elements.

### DETAILED DESCRIPTION

Components (e.g., plasma-facing components such as a dielectric window or top plate/lid, an edge ring, etc.) in a processing chamber of a substrate processing system may be exposed to plasma, including radicals, ions, reactive species, etc., within the processing chamber. Exposure to the plasma may cause portions of the components, such as ceramic layers of components, to erode (i.e., wear) over time due to process mechanisms including, but not limited to, fluoridation, ion bombardment, etc. Such wear may allow materials of the components to migrate into a reaction volume of the processing chamber, which may adversely affect substrate processing, which may be referred to as particle generation. For example, direct molecular and/or particle material removed from the components may be suspended within plasma, and may be deposited on an edge ring or other process chamber components. This material can then be redeposited on the surface of the substrate during subsequent processing. In other words, wear of components due to exposure to plasma may cause particle generation and contamination of the process chamber, resulting in substrate defects. Wear of the components also reduces a useful life of the components.

In some examples, coatings are applied to the components to reduce wear, enhance stability and longevity, and maintain structural and/or electrical properties of the components. However, many coatings fail to sufficiently reduce wear and particle generation in processes using greater power and/or temperatures and various corrosive materials. Some coatings may have structural weaknesses inherent to the material and/or coating process. For instance, plasma spray processes may embed non-melted particles into the coating that are subsequently released into the processing chamber as the coating erodes. Various other processes including, but not limited to, physical vapor deposition (PVD), atomic layer deposition (ALD), chemical vapor deposition (CVD), plasma enhanced CVD (PECVD), etc. may also cause erosion and particle generation of the coating.

Coating systems and methods according to the principles of the present disclosure apply an enhanced coating to components of a processing chamber in a substrate processing system. For example, a ceramic coating is applied to a substrate surface of a component. The substrate of the component may comprise any suitable material capable of withstanding temperatures associated with the coating process including, but not limited to, aluminum, silicon, alumina, etc. The coating may be applied using low porosity aerosol deposition, PVD, CVD, thermal spraying, etc. at a low temperature (e.g., less than 400 degrees Celsius or, in some examples, less than 300 degrees Celsius).

The coating comprises a plasma-resistant ceramic material such as a rare earth oxide (e.g., yttrium oxide, or Y₂O₃). While yttrium oxide is discussed herein, the coating material may comprise other rare earth oxides and/or mixtures (e.g., mixtures with aluminum) may be used, including, but not limited to, ytterbium, erbium, dysprosium, gadolinium, thulium, and aluminum oxides. Another example material is yttrium aluminum monoclinic oxide (Y₄Al₂O₉). A grain size of the material in the deposited coating is less than 150 nm and, in some examples, is less than 100 nm. The coating has a thickness of less than 30 microns (μm), and preferably a thickness of 3-20 microns.

The component including the ceramic coating is then inserted into a heat treatment chamber such as a high temperature oven (e.g., a furnace or a kiln). The oven temperature is elevated to a temperature sufficient to sinter the coating according to parameters described below in more detail and then allowed to cool. Sintering of some ceramic materials (e.g., rare earth oxides such as yttrium oxide) may typically require temperatures greater than 1400 degrees Celsius. For example, sintering temperatures may correspond to temperatures required to melt particles of a respective material. However, sintering of the material according to the present disclosure may be performed at temperatures less than typical sintering temperatures. In other words, the sintering of the present disclosure is performed at a temperature that is less than a melting temperature of the material of the coating.

For example, the sintering according to the present disclosure may be performed on yttrium oxide at temperatures less than 1300 degrees Celsius and, in some examples, less than 1200 degrees Celsius. In this manner, particles of the material experience diffusion and grain growth resulting in structural properties similar to bulk ceramics without increasing the porosity and stress of the material caused by melting. For example, the coating material according to the principles of the present disclosure may have an increased resistance to chemical etching demonstrated by less than 300 nm of erosion caused by a one hour acid soak test in a 5% hydrogen chloride (HCl) solution.

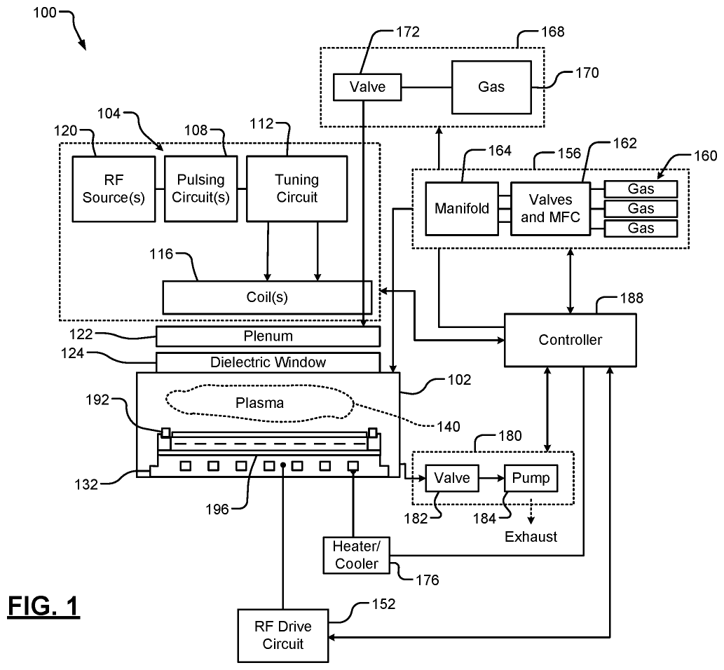

Referring now to FIG. 1, an example of a substrate processing system 100 including a processing chamber 102 is shown. While a specific substrate processing system 100 is shown simply to illustrate example components of a processing chamber 102, the principles of the present disclosure may be applied to other types of substrate processing systems and processing chambers. The substrate processing system 100 or another type of substrate processing system may be used to perform a deposition process (e.g., an aerosol deposition process) to apply the coating according to the principles of the present disclosure.

The substrate processing system 100 includes a coil driving circuit 104. A pulsing circuit 108 may be used to pulse the RF power on and off or vary an amplitude or level of the RF power. A tuning circuit 112 may be directly connected to one or more inductive coils 116. The tuning circuit 112 tunes an output of an RF source 120 to a desired frequency and/or a desired phase, matches an impedance of the coils 116 and splits power between the coils 116. In some examples, the coil driving circuit 104 may be replaced by a drive circuit as described further below in conjunction with controlling the RF bias.

In some examples, a plenum 122 may be arranged between the coils 116 and a dielectric window 124 to control the temperature of the dielectric window 124 with hot and/or cold air flow. The dielectric window 124 is arranged along one side of the processing chamber 102. The processing chamber 102 further comprises a substrate support (or pedestal) 132. The substrate support 132 may include an electrostatic chuck (ESC), or a mechanical chuck or other type of chuck. Process gas is supplied to the processing chamber 102 and plasma 140 is generated inside of the processing chamber 102. The plasma 140 etches an exposed surface of a substrate 144. A drive circuit 152 (such as one of those described below) may be used to provide an RF bias to an electrode in the substrate support 132 during operation.

A gas delivery system 156 may be used to supply a process gas mixture to the processing chamber 102. The gas delivery system 156 may include process and inert gas sources 160, a gas metering system 162 such as valves and mass flow controllers, and a manifold 164. A gas delivery system 168 may be used to deliver gas 170 via a valve 172 to the plenum 122. The gas may include cooling gas (air) that is used to cool the coils 116 and the dielectric window 124. A heater/cooler 176 may be used to heat/cool the substrate support 132 to a predetermined temperature. An exhaust system 180 includes a valve 182 and pump 184 to remove reactants from the processing chamber 102 by purging or evacuation.

A controller 188 may be used to control the etching process. The controller 188 monitors system parameters and controls delivery of the gas mixture, striking, maintaining and extinguishing the plasma, removal of reactants, supply of cooling gas, and so on. Additionally, as described below in detail, the controller 188 may control various aspects of the coil driving circuit 104 and the drive circuit 152. An edge ring 192 may be located radially outside of the substrate 134 during plasma processing.

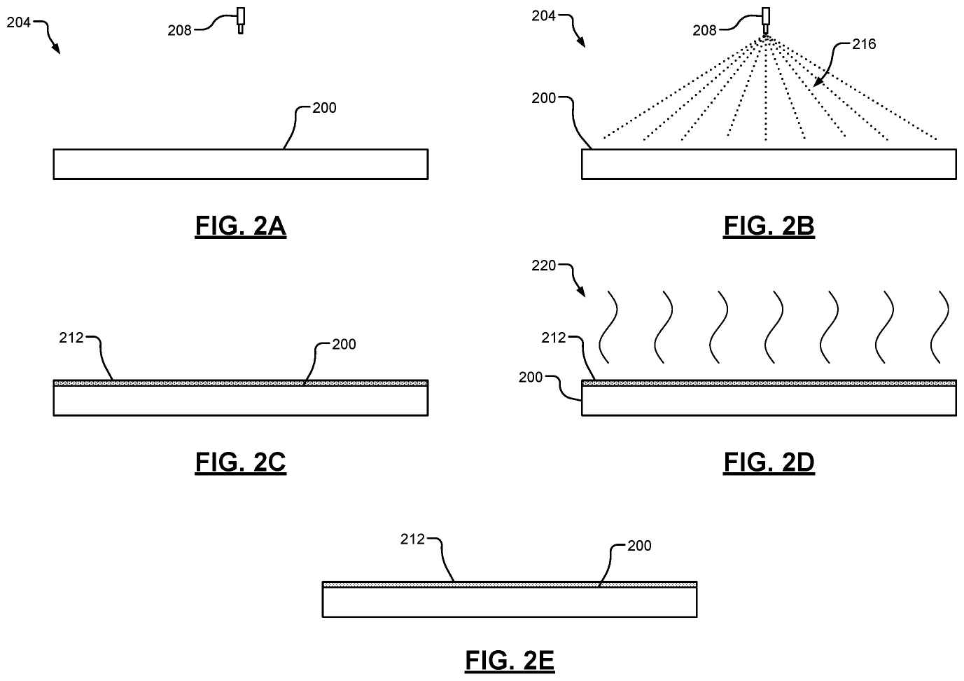

Referring now to FIGS. 2A through 2E, a coating and sintering process according to the present disclosure is shown. As shown in FIG. 2A, a component 200 is arranged within a processing chamber 204. For example, the component 200 corresponds to a dielectric window and the processing chamber 204 corresponds to a plasma etching chamber. The component 200 may comprise a material capable of withstanding temperatures associated with the coating process including, but not limited to, aluminum, silicon, alumina, etc. For example only, a dielectric window may comprise a ceramic material. The processing chamber 204 may include a gas distribution device 208 such as a showerhead, nozzle, etc. For example only, the gas distribution device 208 is shown as a nozzle.

As shown in FIGS. 2B and 2C, an aerosol deposition process is performed within the processing chamber 204 to apply a coating 212 on the component 200. For example, the gas distribution device 208 is configured to supply an aerosolized material 216 into the processing chamber 204 to implement the aerosol deposition process. The coating 212 is applied while a temperature within the processing chamber 204 is maintained at less than 400 degrees Celsius (e.g., between 0 and 400 degrees Celsius). The aerosolized material 216 comprises a plasma-resistant ceramic material such as a rare earth oxide (e.g., yttrium oxide, or Y₂O₃). A grain size of the material is less than 150 nm and, in some examples, is less than 100 nm. The applied coating 212 has a thickness of less than 30 microns (e.g., a thickness of 3-20 microns).

As shown in FIG. 2D, the component 200 including the coating 212 is transferred to an oven or kiln 220 for a heat treatment process. During the heat treatment process, the temperature within the oven 220 is elevated to a temperature sufficient to cause diffusion and grain growth of the material of the coating 212 resulting in structural properties similar to bulk ceramics without increasing the porosity and stress of the material of the coating 212 caused by melting. For example, sintering of yttrium oxide may typically require temperatures greater than 1400 degrees Celsius. Conversely, in the heat treatment process according to the present disclosure, the temperature of the oven 220 is only increased to a temperature that is less than 1400 degrees Celsius to maximize grain growth while minimizing porosity of the coating 212.

For example, the temperature of the oven 220 may be increased (e.g., ramped upward) from an initial temperature to a maximum temperature that is less than 1400 degrees Celsius over a predetermined period. In one example, the temperature is increased from an initial temperature of 500 degrees Celsius to a maximum temperature of 1300 degrees Celsius. For example only, the temperature may be increased from the initial temperature to the maximum temperature over a first period (e.g., between 5 and 30 hours) and maintained (“soaked”) at the maximum temperature for a second period (e.g., between 8 and 144 hours). The temperature may be increased at a predetermined ramp rate in accordance with properties of the materials of the component 200 and/or the coating 212. In some examples, the ramp rate is 30 degrees Celsius per hour. In other examples, the ramp rate is 100 degrees Celsius per hour. The temperature may be decreased (i.e., ramped downward) in a third period to allow the component 200 to cool subsequent to the second period.

In another example, the heat treatment process may include multiple ramp periods and/or soak periods. For example, the heat treatment process may include increasing the temperature from an initial temperature (e.g., 500 degrees Celsius) to an intermediate temperature (e.g., 900 degrees Celsius) over a first period and maintaining the intermediate temperature for a second period. Subsequent to the second period, the temperature may be increased from the intermediate temperature to a maximum temperature (e.g., 1300 degrees Celsius) over a third period and maintained at the maximum temperature for a fourth period. The temperature may be decreased in a fifth period to allow the component 200 to cool subsequent to the fourth period.

FIG. 2E shows the coating 212 subsequent to the heat treatment process. As a result of the heat treatment process performed on the material having the characteristics described above in FIGS. 2A-2C, the coating 212 has a porosity of less than 20%, an average grain size between 200 and 700 nm, and a surface roughness of less than 0.1 Sa. Further, the coating 212 subsequent to the heat treatment process according to the principles of the present disclosure has an increased resistance to chemical etching demonstrated by less than 300 nm of erosion caused by a one hour acid soak test in a 5% hydrogen chloride (HCl) solution.

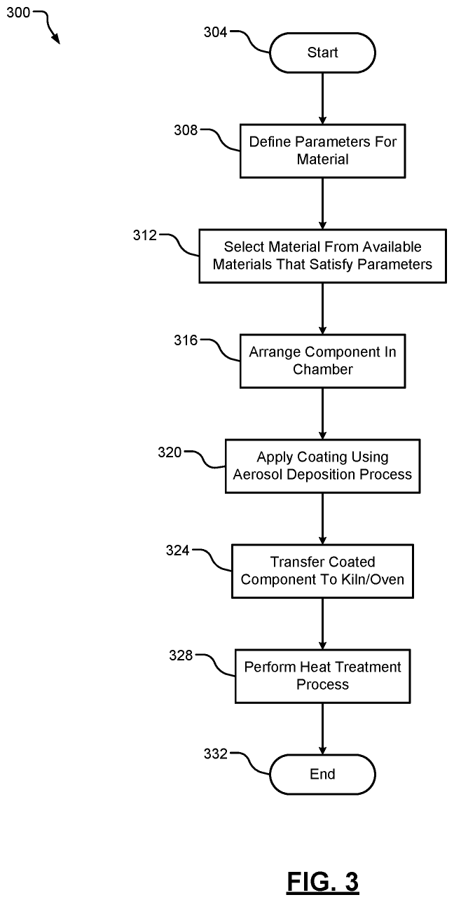

Referring now to FIG. 3, an example method 300 for applying and performing a heat treatment on a coating of a component of a substrate processing chamber according to the present disclosure begins at 304. At 308, the method 300 (e.g., a user) defines one or more parameters for a material to be applied to a component of a processing chamber in a coating step. For example, a grain size of the material may be defined. The grain size may be defined to be less than 150 nm and, in some examples, less than 100 nm. Another example parameter is resistance to plasma etching and/or erosion caused by other chemical mixtures within the processing chamber.

At 312, the method 300 (e.g., a user) selects a material from available materials that satisfy the defined parameters. Example materials may include rare earth oxide mixtures including, but not limited to, ytterbium, erbium, dysprosium, gadolinium, thulium, and aluminum oxide mixtures. In one example, the material corresponds to an yttrium oxide mixture having a grain size less than 150 nm and capability of being applied in a coating having a thickness between 3 and 20 microns.

At 316, the component is arranged in a suitable processing chamber, such as a plasma etching chamber. At 320, an aerosol deposition process is performed within the processing chamber to apply a coating of the selected material. For example, the selected material is supplied to the processing chamber in aerosolized form as described above while a temperature within the processing chamber is maintained at less than 400 degrees Celsius (e.g., between 0 and 400 degrees Celsius). The coating has a thickness of 3-20 microns.

At 324, the component including the coating is transferred to an oven or kiln for a heat treatment process. At 328, the heat treatment process is performed on the component as described above in FIGS. 2D and 2E. For example, the temperature within the oven is elevated to a temperature sufficient to cause diffusion and grain growth of the material of the coating resulting in structural properties similar to bulk ceramics without increasing the porosity and stress of the material of the coating caused by melting. For example, for an yttrium oxide mixture, the temperature of the oven is increased from an initial temperature of 500 degrees Celsius to a maximum temperature of 1300 degrees Celsius. The heat treatment process may include multiple ramp periods and/or soak periods and a cooling period as described above. The method 300 ends at 332. Although as described above the heat treatment process is performed in a different chamber than the aerosol deposition process, in some examples both the application of the coating and the heat treatment process may be performed in the same chamber.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method for forming a coating on a component of a substrate processing system, the method comprising:
arranging the component in a processing chamber;
applying a ceramic material to form the coating on one or more surfaces of the component, wherein the ceramic material is comprised of a mixture including a rare earth oxide and a grain size of the mixture is less than 150 nm, wherein the ceramic material is applied while a temperature within the processing chamber is less than 400 degrees Celsius, and wherein the coating has a thickness of less than 30 μm;
arranging the component in a heat treatment chamber; and
performing a heat treatment process on the component including the coating, wherein the heat treatment process includes increasing a temperature of the heat treatment chamber from a first temperature to a second temperature over a first period and maintaining the heat treatment chamber at the second temperature for a second period, wherein the second temperature does not exceed a melting temperature of the mixture.

2. The method of claim 1, wherein the processing chamber is configured to perform plasma etching.

3. The method of claim 1, wherein the component is a dielectric window.

4. The method of claim 1, wherein applying the ceramic material includes applying the ceramic material using aerosol deposition.

5. The method of claim 1, wherein applying the ceramic material includes applying the ceramic material using at least one of physical vapor deposition, chemical vapor deposition, and thermal spraying.

6. The method of claim 1, wherein the mixture includes yttrium oxide.

7. The method of claim 6, wherein the second temperature is less than 1400 degrees Celsius.

8. The method of claim 6, wherein the second temperature is less than 1300 degrees Celsius.

9. The method of claim 1, wherein the mixture includes at least one of ytterbium, erbium, dysprosium, gadolinium, thulium, and aluminum.

10. The method of claim 1, wherein the grain size is less than 100 nm.

11. The method of claim 1, wherein the thickness of the coating is 3-20 μm.

12. The method of claim 1, wherein the first period is between 5 and 30 hours and the second period is between 8 and 144 hours.

13. The method of claim 1 wherein the temperature of the heat treatment chamber is increased during the first period at a predetermined ramp rate.

14. The method of claim 13, wherein the ramp rate is 30-100 degrees Celsius per hour.

15. The method of claim 1, further comprising increasing the second temperature to a third temperature over a third period and maintaining the heat treatment chamber at the third temperature for a fourth period, wherein the third temperature does not exceed the melting temperature of the mixture.

16. The method of claim 1, wherein, subsequent to the heat treatment process, the coating has a porosity less than 20%.

17. The method of claim 1, wherein, subsequent to the heat treatment process, the coating has an average grain size between 200 and 700 nm.

18. The method of claim 1, wherein, subsequent to the heat treatment process, the coating has a surface roughness less than 0.1 Sa.

19. The method of claim 1, wherein, subsequent to the heat treatment process, the coating experiences less than 30 nm of erosion caused by a one hour acid soak test in a 5% hydrogen chloride solution.
